(19) United States
(12) Patent Application Publication
(10) Pub. No.: US 2009/0230490 A1
(43) Pub. Date: Sep. 17, 2009

(54) SOLID-STATE IMAGING DEVICE AND METHOD FOR MANUFACTURING THE SAME

(76) Inventor: Kenji YOKOZAWA, Shiga (JP)

Correspondence Address: MCDERMOTT WILL & EMERY LLP, 600 13TH STREET, NW, WASHINGTON, DC, 20005-3096, US

(21) Appl. No.: 12/370,052

(22) Filed: Feb. 12, 2009

(30) Foreign Application Priority Data
Mar. 14, 2008 (JP) 2008-065849

(51) Int. Cl. H01L 31/101; H01L 21/02

(52) U.S. Cl. 257/432; 438/70; 257/E21.002; 257/E31.054

(57) ABSTRACT

A solid-state imaging device includes: photoelectric transducers arranged in a matrix pattern on a substrate; and a plurality of color filter layers of different colors formed above the photoelectric transducers so as to correspond to the photoelectric transducers. One of the color filter layers of the color, which accounts for a largest area, is formed by two layers which are a bottom layer and a top layer of the color filter layers.

### CROSS REFERENCE TO RELATED APPLICATION

This application claims priority under 35 U.S.C. §119 on Patent Application No. 2008-65849 filed in Japan on Mar. 14, 2008, the entire contents of which are hereby incorporated by reference.

### BACKGROUND OF THE INVENTION

The present invention relates to a color solid-state imaging device and a method for manufacturing the same. More particularly, the present invention relates to a color solid-state imaging device having color filter layers which are made of a photosensitive resin, or the like, including dispersed therein a coloring agent such as a pigment, a dye, or the like, and a method for manufacturing the same.

A color solid-state imaging device includes color filter layers (pigment layers), each corresponding to a different photoelectric transducer, which are arranged in a predetermined pattern for obtaining color images (see, for example, Japanese Laid-Open Patent Publication No. 11-150252; hereinafter “Patent Document 1”). Each color filter layer used in a color solid-state imaging device is formed by applying, exposing, developing and curing a photosensitive resin, or the like, including dispersed therein a coloring agent such as a pigment, a dye, or the like, on a substrate. Referring to FIGS. 15-20B, the structures of conventional solid-state imaging devices including color filter layers will be described.

FIG. 15 is a plan view showing color filter layers provided in a conventional solid-state imaging device as disclosed in Patent Document 1, for example, as viewed from the lens side. Typically, a single-chip color solid-state imaging device, which uses a color filter including color filter layers of three primary colors of light placed on a solid-state imaging device, often uses color filter layers arranged in a Bayer array.

As shown in FIG. 15, a color filter 20 includes green color filter layers 20G arranged in a checker pattern, and includes blue color filter layers 20B and red color filter layers 20R alternating with each other by rows or by columns to fill the open spots in the checker pattern. In other words, a repetitive pattern of green, red, green, red, . . . , occurs in a row (e.g., a row along line XVIa-XVIa in FIG. 15), and a repetitive pattern of blue, green, blue, green, . . . , occurs in the next row. Similarly, a repetitive pattern of green, red, green, red, . . . , occurs in a column, and a repetitive pattern of blue, green, blue, green, . . . , occurs in the next column.

FIGS. 16A to 17B are schematic cross-sectional views showing a conventional solid-state imaging device as disclosed in Patent Document 1, wherein FIGS. 16A and 17A are cross-sectional views taken along line XVIa-XVIa in FIG. 15, and FIGS. 16B and 17B are cross-sectional views taken along line XVIb-XVIb in FIG. 15.

As shown in FIGS. 16A to 17B, the conventional solid-state imaging device includes an N-type semiconductor substrate 11 and a P-type well layer 12 formed on the N-type semiconductor substrate 11, with a plurality of photoelectric transducers 13 formed in an upper portion of the P-type well layer 12 for photoelectric conversion as an N-type semiconductor layer. A gate insulating film 14 is formed so as to cover the P-type well layer 12 and the photoelectric transducers 13, and a transfer electrode 15 for transferring a signal is formed on the gate insulating film 14 between the photoelectric transducers 13. An interlayer insulating film 16 is formed on the side surface and the upper surface of the transfer electrode 15 so that the transfer electrode 15 is covered by the interlayer insulating film 16, and a light blocking film 17 is formed on the side surface and the upper surface of the interlayer insulating film 16 so that the interlayer insulating film 16 is covered by the light blocking film 17. The light blocking film 17 is formed by tungsten, or the like, and serves to prevent unnecessary light from being incident on portions other than the photoelectric transducers 13. A passivation film 18 is formed so as to cover the gate insulating film 14 and the light blocking film 17. Since the layer underlying the passivation film 18 is not flat, the passivation film 18 is formed with depressed portions on the upper surface thereof. A first transparent flattening layer 19a is formed in the depressed portions of the passivation film 18, and a second transparent flattening layer 19b of a thermosetting transparent resin is formed on the flattened upper surface of the passivation film 18 and the first transparent flattening layer 19a. Moreover, the color filter 20 is formed on the second transparent flattening layer 19b. The second transparent flattening layer 19b serves to improve the adhesion of the color filter 20 and also to reduce the development residue. The color filter 20 is a collection of color filter layers of predetermined pigments (green, red and blue) for different pixels, i.e., the green color filter layers 20G, the red color filter layers 20R and the blue color filter layers 20B, wherein the color filter layers are arranged in an array as shown in FIG. 15. A third transparent flattening layer 19c is formed on the color filter 20, and an array of microlenses 22 is formed on the third transparent flattening layer 19c. Each microlens 22 is in a convex lens corresponding to the color filter layer and the photoelectric transducer 13 of one pixel, and serves to improve the efficiency in collecting light onto the photoelectric transducer 13 of the pixel.

In the conventional solid-state imaging device of Patent Document 1, the color filter 20 is formed as follows. That is, the green color filter layers 20G, which account for the largest portion of the sensing area among the red, green and blue color filter layers, are formed on the flattening film 19b as the first layer of the color filter 20. Therefore, since the green color filter layers 20G have a large contact area with the underlying flattening film 19b, the adhesion therebetween is improved and the exfoliation therebetween is prevented. Then, the second and third layers of the color filter 20, e.g., the red color filter layers 20R and the blue color filter layers 20B, respectively, are formed as follows. That is, the red color filter layers 20R or the blue color filter layers 20B are formed so that the edge thereof overlaps the edge of the green color filter layers 20G. Therefore, since not only the portion of the red color filter layers 20R or the blue color filter layers 20B in direct contact with the underlying layer, but also the overlapping portion is bonded, the adhesion is improved. In the color filter 20 with an overlap between edge portions, there is no gap between adjacent color filter layers, thereby increasing the area of the color filter 20 in direct contact with the underlying layer. The green color filter layer 20G of each unit pixel has a larger area than the red color filter layer 20R or the blue color filter layer 20B to such an extent that there is no influence from adjacent pixels. Thus, the green color filter layer 20G has an increased contact area with the underlying layer, thereby preventing the exfoliation and the peeling-off thereof.

When blue light is incident on a boundary portion between a green pixel and a red pixel in the conventional solid-state imaging device of Patent Document 1, the blue light is absorbed by the green color filter layer 20G present in the boundary portion with only a small amount of the blue light passing through the green color filter layer 20G to be diffusely reflected by the surface of the light blocking film 17, etc. As a result, the amount of light to be received by a photoelectric transducer 13G located under the green color filter layer 20G interposed between the red color filter layers 20R does not substantially change. Although not shown in the figure, also when blue light is incident on a boundary portion between a green pixel and a blue pixel, the blue light is absorbed by the green color filter layer 20G present in the boundary portion with only a small amount of the blue light passing through the green color filter layer 20G to be diffusely reflected by the surface of the light blocking film 17, etc. As a result, the amount of light to be received by the photoelectric transducer 13G located under the green color filter layer 20G interposed between the blue color filter layers 20B does not substantially change. Thus, even if blue light is incident on a pixel boundary portion, the amount of light to be received by the photoelectric transducer 13G located under the green color filter layer 20G interposed between the red color filter layers 20R will not be different from the amount of light to be received by the photoelectric transducer 13G located under the green color filter layer 20G interposed between the blue color filter layers 20B.

This similarly holds true when the incident light is red light. When red light is incident on a boundary portion between a green pixel and a red pixel, the red light is absorbed by the green color filter layer 20G present in the boundary portion with only a small amount of the red light passing through the green color filter layer 20G to be diffusely reflected. As a result, the amount of light to be received by the photoelectric transducer 13G located under the green color filter layer 20G interposed between the red color filter layers 20R does not substantially change. Also when red light is incident on a boundary portion between a green pixel and a blue pixel, the red light is absorbed by the green color filter layer 20G present in the boundary portion with only a small amount of the red light passing through the green color filter layer 20G to be diffusely reflected. As a result, the amount of light to be received by the photoelectric transducer 13G located under the green color filter layer 20G interposed between the blue color filter layers 20B does not substantially change. Thus, even if red light is incident on a pixel boundary portion, the amount of light to be received by the photoelectric transducer 13G located under the green color filter layer 20G interposed between the red color filter layers 20R will not be different from the amount of light to be received by the photoelectric transducer 13G located under the green color filter layer 20G interposed between the blue color filter layers 20B.

Thus, the color filter 20 is formed so that the green color filter layer 20G is larger than the pixel size and so that the edge of the green color filter layer 20G overlaps the edge of the red color filter layer 20R or the blue color filter layer 20B. Then, the sensitivity of the photoelectric transducer 13G located under the green color filter layer 20G interposed between the red color filter layers 20R or the blue color filter layers 20B will not be different from that of others, thereby preventing line noise from occurring due to the arrangement of pixels forming rows and columns of the color filter 20.

FIGS. 4A and 4B are spectral characteristics showing the absorption of red light and blue light by the green color filter layers 20G. As shown in FIGS. 4A and 4B, red light and blue light are absorbed by green filter layers.

Therefore, in the color filter of Patent Document 1, the edge of the green color filter layers 20G overlaps the edge of the red color filter layers 20R or the blue color filter layers 20B, thereby improving the adhesion between the color filter layers and preventing line noise from occurring due to sensitivity non-uniformity.

FIG. 18 is a plan view of a color filter of another conventional solid-state imaging device as disclosed in Japanese Laid-Open Patent Publication No. 2001-21715 (hereinafter “Patent Document 2”). FIGS. 19A to 20B are schematic cross-sectional views showing the structure of FIG. 18, wherein FIGS. 19A and 20A are cross-sectional views taken along line XIXa-XIXa in FIG. 18, and FIGS. 19B and 20B are cross-sectional views taken along line XIXb-XIXb in FIG. 18.

As shown in FIG. 18, a color filter of Patent Document 2 includes the green color filter layers 20G arranged in a checker pattern, as are those in the conventional solid-state imaging device of Patent Document 1, with the green color filter layers 20G being coupled together in diagonal directions by means of bridge portions. Then, the gap between pixels is filled up to improve the adhesion, and it is possible to eliminate the difference between the amount of light to be received by the photoelectric transducer 13G located under the green color filter layer 20G interposed between the red color filter layers 20R and the amount of light to be received by the photoelectric transducer 13G located under the green color filter layer 20G interposed by the blue color filter layers 20B.

Thus, the color filter of Patent Document 2 employs a structure where the green color filter layers 20G are coupled together in diagonal directions by means of bridge portions, whereby it is possible to improve the adhesion of the color filter and to prevent line noise from occurring due to sensitivity non-uniformity.

### SUMMARY OF THE INVENTION

However, the conventional solid-state imaging devices of Patent Documents 1 and 2, which are provided with a color filter in which the green filter layer 20G is larger than the pixel size, have the following problems.

First, as shown in FIGS. 17A, 17B, 20A and 20B, where an oblique light beam “a” is incident on a pixel boundary portion, since the green filter layers 20G are larger, the oblique light beam “a” may pass through the green filter layer 20G and be incident on the red filter layer 20R or the blue color filter layer 20B. This causes mixture of colors, thereby failing to obtain a high-definition image.

Moreover, as shown in FIGS. 17A, 17B, 20A and 20B, where an oblique light beam “b” is incident on a pixel boundary portion, the oblique light beam “b” may pass through the green color filter layer 20G and then be incident on a photoelectric transducer 13R of a red pixel located under the adjacent red filter layer 20R. As a result, a portion of a short-wavelength component of the green wavelength range is added to the red spectral characteristics, thereby increasing the sensitivity for red. Similarly, where the oblique light beam “b” passes through the green color filter layer 20G and is then incident on a photoelectric transducer 13B of a blue pixel located under the adjacent blue filter layer 20B, a portion of a long-wavelength component of the green wavelength range is added to the blue spectral characteristics, thereby increasing the sensitivity for blue. Then, the overall sensitivity will be inaccurate.

Moreover, where the green color filter layer 20G is designed (resized) to be larger than the pixel size to suppress line noise, as in the color filter of Patent Document 1, it is difficult to optimize the amount of resizing for the particular solid-state imaging device. Specifically, it is very difficult to determine an amount of resizing with which oblique light beams have little influence and which is effective in suppressing line noise.

In order to realize desirable spectral characteristics, it is necessary to apply a color resist to be a color filter layer with a sufficient thickness. However, as the color resist becomes thicker, it is more likely that ultraviolet radiation (i line), for example, used in the exposure step in a photolithography process is absorbed by the color resist being irradiated with the i line, whereby the i line will not reach a deep portion. With the exposure of a deep portion being insufficient, the photopolymerization will be insufficient, whereby exfoliation occurs more easily. Moreover, it is very difficult to granulate pigment particles, and even if granulation is achieved, an increase in the secondary particle size due to the dispersion process is inevitable. Therefore, it is difficult to realize a thin pigment-dispersed color resist. The exposure time has been extended in order to prevent exfoliation due to insufficient photopolymerization. However, an increase in the exposure time also increases the amount of time over which the incident light repeats diffuse reflection by pigment particles, thereby deteriorating the edge shape. Then, high-definition images may not be obtained by the solid-state imaging device.

Moreover, in the conventional solid-state imaging device, since the color filter layer has a large thickness as described above, the edge thereof as seen in a cross-sectional view is not vertical to the substrate but is slanted at an angle. In other words, the green color filter layers 20G to be formed in the first layer each have a trapezoidal cross section (upper side length<lower side length). In the solid-state imaging device of Patent Document 1, the color filter layers in the second layer (e.g., the red color filter layers 20R) and those in the third layer (e.g., the blue color filter layers 20B) are formed so as to cover the edge of the pattern of the green color filter layer 20G formed in the first layer, whereby the edge portion of the red color filter layer 20R and the blue color filter layer 20B stands higher from the photoelectric transducer 13 than the central portion thereof. As a result, as shown in FIG. 17A, an oblique light beam is more likely to pass through the edge portion of the color filter layer of an adjacent pixel, thereby failing to realize desirable spectral characteristics and resulting in mixture of colors.

Particularly, in a structure where edges of color filter layers overlap each other, the color filter has an increased thickness and the distance from the photoelectric transducer 13 to the microlens 22 is longer in a boundary portion between adjacent pixels. This adversely influences the optical characteristics of the solid-state imaging device.

Another problem is that the alignment margin in the cross section of the color filter 20 decreases as the pixel size is reduced. If there is a misalignment, incident light passes through the peripheral portion of the color filter layer of an adjacent pixel, thus resulting in more significant mixture of colors, thereby failing to realize desirable spectral characteristics.

When green color filter layers are formed in a checker pattern in a color filter of the Bayer arrangement, the poor resolution of the color resist material may deteriorate the edge shape of the color filter layers in the peripheral region, and in some cases, the outline of the color filter layers may be deformed. Such an outline deformation has no regularity, and it is therefore difficult to address the problem with mask designs.

In the solid-state imaging device of Patent Document 2, in the formation of green filter layers being a colored pattern formed in the first layer, the checker pattern of unit pixels are coupled together by means of connecting portions. In practice, however, due to the poor resolution of the photosensitive colored resist, it is difficult to keep the shape of the connecting portions if the pixel size is reduced. As a result, the thickness and shape of the connecting portions will be non-uniform, and in worst cases, the connecting portions may not be formed at all or the shape of the unit pixel may be deformed. Moreover, the red and blue filter layers are formed afterwards in regions surrounded by the green filter layers. Therefore, if there is a misalignment, adjacent color filter layers may have a gap therebetween or the red and blue color filter layers may overlap the green filter layers. As a result, the obtained color filter will not be flat, whereby it is difficult to reduce the thickness of the flattening film under the microlens array, and the shape of the microlenses formed afterwards may be non-uniform. A solid-state imaging device manufactured with these problems will have poor optical characteristics due to sensitivity non-uniformity. Moreover, if a reduction in the thickness of a solid-state imaging device is not realized, it is expected that optical characteristics thereof, e.g., the sensitivity, the smear, the shading, etc., will be deteriorated.

In view of these problems in the prior art, the present invention has an object to address the reduction in the pixel sizes by realizing a large alignment margin and realizing the formation of a gap-less, stable color filter, whereby it is possible to prevent problems such as sensitivity non-uniformity and mixture of colors, and to realize desirable optical characteristics in terms of the sensitivity, the smear, the shading, etc.

In order to achieve the object set forth above, the present invention provides a solid-state imaging device in which one of color filter layers, which accounts for the largest portion of the sensing area, is formed in two separate steps.

Specifically, a solid-state imaging device of the present invention includes: photoelectric transducers arranged in a matrix pattern on a substrate; and a plurality of color filter layers of different colors formed above the photoelectric transducers so as to correspond to the photoelectric transducers, wherein one of the color filter layers of the color, which accounts for a largest area, is formed by two layers which are a bottom layer and a top layer of the color filter layers.

With the solid-state imaging device of the present invention, the edge portion of each pixel is formed precisely, thus improving the dimension non-uniformity. This reduces variations from line to line of the sensitivity for incident light, thus improving the mixture of colors, the line noise, the sensitivity non-uniformity, etc. In the exposure step of forming the bottom layer and the top layer, light is more likely to reach the inside, whereby it is possible to prevent the exfoliation due to insufficient photopolymerization.

In the solid-state imaging device of the present invention, it is preferred that the bottom layer is wider than the top layer.

This increases the contact area and the adhesion between the underlying layer and the bottom layer of the one of the color filter layers, which accounts for the largest portion of the sensing area. Moreover, since the top layer is formed on the bottom layer, the adhesion is reinforced.

In the solid-state imaging device of the present invention, it is preferred that the bottom layer is wider than the top layer, and the top layer is wider than any of the other color filter layers.

Then, the bottom layer and the top layer of the one of the color filter layers are each formed to be larger than the pixel size with a larger width than those of the other color filter layers, whereby it is possible to eliminate the gap between adjacent pixels.

In the solid-state imaging device of the present invention, it is preferred that: the one of the color filter layers has a thickness such that a sum of a thickness of the bottom layer and that of the top layer yields desirable spectral characteristics; and the thickness of the bottom layer is less than or equal to ½ the thickness of the one of the color filter layers.

Then, the shape of the edge portion of the bottom layer can be improved to be closer to being vertical to the substrate, and the dimension precision can be improved. Therefore, it is possible to form a bottom layer with a little deformation. Moreover, in the exposure step of forming the bottom layer, the bottom layer can be sufficiently photopolymerized.

In the solid-state imaging device of the present invention, it is preferred that the one of the color filter layers has a thickness such that a sum of a thickness of the bottom layer and that of the top layer yields desirable spectral characteristics; and the thickness of the top layer is greater than or equal to ½ the thickness of the one of the color filter layers.

Then, the thickness of the bottom layer can be made less than or equal to ½ the desired thickness of the one of the color filter layers, whereby it is possible to form the bottom layer with a little deformation. Moreover, in the exposure step of forming the one of the color filter layers, the bottom layer and the top layer can be sufficiently photopolymerized.

In the solid-state imaging device of the present invention, it is preferred that edge portions of the other color filter layers are interposed between the bottom layer and the top layer.

Then, it is possible to reduce the height and angle of the rise of the edge portions of the other color filter layers formed on the bottom layer. Thus, it is possible to improve the shape of the edge portions of the other color filter layers. The edge portions of the other color filter layers formed on the bottom layer are interposed between the bottom layer and the top layer, and the top layer is therefore formed so as to fill portions where the other color filter layers are absent. Thus, the edge portion of each pixel is formed precisely, and there will be no gap between adjacent pixels, thereby improving the dimension non-uniformity. Therefore, it is possible to prevent line noise occurring due to light being incident on a pixel boundary portion. The mixture of colors from adjacent color filter layers can be prevented even if a light beam oblique with respect to the substrate is incident on a pixel boundary portion, whereby it is possible to improve the mixture of colors, the line noise and the sensitivity non-uniformity.

In the solid-state imaging device of the present invention, it is preferred that the one of the color filter layers is a green color filter layer.

In the solid-state imaging device of the present invention, it is preferred that the one of the color filter layers is a green color filter layer, and the other color filter layers are red and blue color filter layers.

A method of the present invention is a method for manufacturing a solid-state imaging device, the solid-state imaging device including photoelectric transducers arranged in a matrix pattern on a substrate, and a plurality of color filter layers of different colors formed above the photoelectric transducers so as to correspond to the photoelectric transducers, the method including the steps of: forming a first layer of one of the color filter layers, which accounts for a largest area, so that the first layer has a thickness less than or equal to ½ a thickness that yields desirable spectral characteristics; forming other color filter layers so that edge portions of the other color filter layers are provided on the first layer; and forming, on the first layer, a second layer of the one of the color filter layers having a width smaller than that of the first layer and a thickness greater than or equal to that of the first layer, so that the edge portions of the other color filter layers are interposed between the first layer and the second layer.

With the method for manufacturing a solid-state imaging device of the present invention, one of the color filter layers, which accounts for the largest portion of the sensing area, can be formed by two layers being the bottom layer and the top layer, forming a plurality of color filter layers. Moreover, it is possible to manufacture a solid-state imaging device in which the edge portions of the other color filter layers are interposed by the two layers of the one of the color filter layers, and the bottom layer and the top layer each having a larger width than those of the other color filter layers, with the bottom layer having a thickness less than or equal to that of the top layer.

In the method for manufacturing a solid-state imaging device of the present invention, it is preferred that the first layer and the second layer are formed by using the same photomask.

Then, it is possible to suppress an increase in the manufacturing cost.

In the method for manufacturing a solid-state imaging device of the present invention, it is preferred that one of the color filter layers is a green color filter layer.

In the method for manufacturing a solid-state imaging device of the present invention, it is preferred that one of the color filter layers is a green color filter layer, and the other color filter layers are red and blue color filter layers.

As described above, with the solid-state imaging device of the present invention and the method for manufacturing the same, it is possible to precisely form a color filter while preventing the exfoliation of color filter layers and the formation of a gap therebetween. Thus, it is possible to obtain a solid-state imaging device having desirable optical characteristics.

### BRIEF DESCRIPTION OF THE DRAWINGS

FIG. 1 is a plan view showing a color filter of a solid-state imaging device according to an example embodiment.

FIGS. 2A and 2B are cross-sectional views showing the solid-state imaging device according to the example embodiment, wherein FIG. 2A is a cross-sectional view taken along line IIa-IIa in FIG. 1, and FIG. 2B is a cross-sectional view taken along line IIb-IIb in FIG. 1.

FIGS. 3A and 3B are cross-sectional views showing the solid-state imaging device according to the example embodiment where light is incident on a pixel boundary portion, wherein FIG. 3A is a cross-sectional view taken along line IIa-IIa in FIG. 1, and FIG. 3B is a cross-sectional view taken along line IIb-IIb in FIG. 1.

FIG. 4A shows spectral characteristics, showing the absorption of blue light by green filter layers, and FIG. 4B shows spectral characteristics, showing the absorption of red light by green filter layers.

FIGS. 5A and 5B are cross-sectional views showing the solid-state imaging device according to the example embodiment where an oblique light beam is incident on a pixel boundary portion, wherein FIG. 5A is a cross-sectional view taken along line IIa-IIa in FIG. 1, and FIG. 5B is a cross-sectional view taken along line IIb-IIb in FIG. 1.

FIG. 6 is a plan view showing a manufacturing process of the solid-state imaging device according to the example embodiment, at a point where the passivation film has been formed.

FIGS. 7A and 7B show the manufacturing process of the solid-state imaging device according to the example embodiment, wherein FIG. 7A is a cross-sectional view taken along line VIIa-VIIa in FIG. 6, and FIG. 7B is a cross-sectional view taken along line VIIb-VIIb in FIG. 6.

FIG. 8 is a plan view showing the manufacturing process of the solid-state imaging device according to the example embodiment, at a point where first green filter layers have been formed.

FIGS. 9A and 9B show the manufacturing process of the solid-state imaging device according to the example embodiment, wherein FIG. 9A is a cross-sectional view taken along line IXa-IXa in FIG. 8, and FIG. 9B is a cross-sectional view taken along line IXb-IXb in FIG. 8.

FIG. 10 is a plan view showing the manufacturing process of the solid-state imaging device according to the example embodiment, at a point where red filter layers and blue filter layers have been formed.

FIGS. 11A and 11B show the manufacturing process of the solid-state imaging device according to the example embodiment, wherein FIG. 11A is a cross-sectional view taken along line XIa-XIa in FIG. 10, and FIG. 11B is a cross-sectional view taken along line XIb-XIb in FIG. 10.

FIG. 12 is a plan view showing the manufacturing process of the solid-state imaging device according to the example embodiment, at a point where second green filter layers have been formed.

FIGS. 13A and 13B show the manufacturing process of the solid-state imaging device according to the example embodiment, wherein FIG. 13A is a cross-sectional view taken along line XIIIa-XIIIa in FIG. 12, and FIG. 13B is a cross-sectional view taken along line XIIIb-XIIIb in FIG. 12.

FIG. 14 is a diagram illustrating how to determine the size of a first green filter layer of the solid-state imaging device according to the example embodiment.

FIG. 15 is a plan view showing an example of a color filter of three primary colors of a conventional solid-state imaging device.

FIGS. 16A and 16B are cross-sectional view showing the conventional solid-state imaging device, wherein FIG. 16A is a cross-sectional view taken along line XVIa-XVIa in FIG. 15, and FIG. 16B is a cross-sectional view taken along line XVIb-XVIb in FIG. 15.

FIGS. 17A and 17B are cross-sectional views showing an oblique light beam being incident on a pixel boundary portion in a cross section of the conventional solid-state imaging device shown in FIG. 15.

FIG. 18 is a plan view showing another example of a color filter of three primary colors of a conventional solid-state imaging device.

FIGS. 19A and 19B are cross-sectional views showing the conventional solid-state imaging device, wherein FIG. 19A is a cross-sectional view taken along line XIXa-XIXa in FIG. 18, and FIG. 19B is a cross-sectional view taken along line XIXb-XIXb in FIG. 18, showing light being incident on a pixel boundary portion.

FIGS. 20A and 20B are cross-sectional views showing the conventional solid-state imaging device shown in FIG. 18 where an oblique light beam is incident on a pixel boundary portion.

### DESCRIPTION OF THE PREFERRED EMBODIMENTS

An example solid-state imaging device will now be described with reference to the drawings.

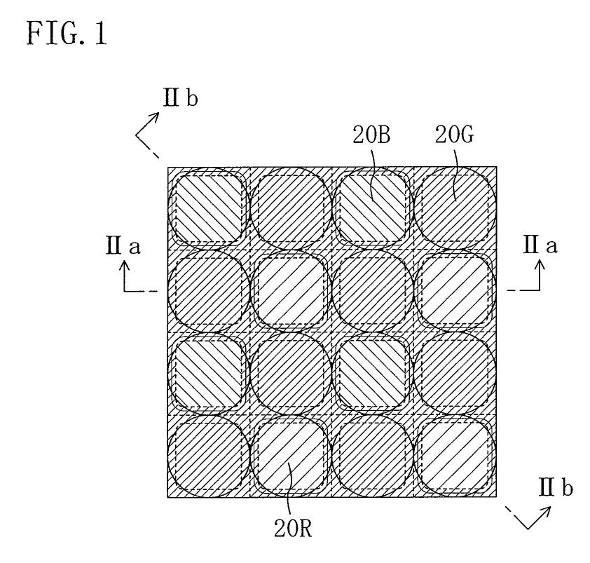

FIG. 1 is a plan view showing a color filter of a solid-state imaging device according to an example embodiment, as viewed from the lens side.

As shown in FIG. 1, the solid-state imaging device of the present embodiment includes a color filter including green color filter layers arranged in a checker pattern, and includes blue color filter layers and red color filter layers alternating with each other by rows or by columns to fill the open spots in the checker pattern, as in the conventional solid-state imaging device.

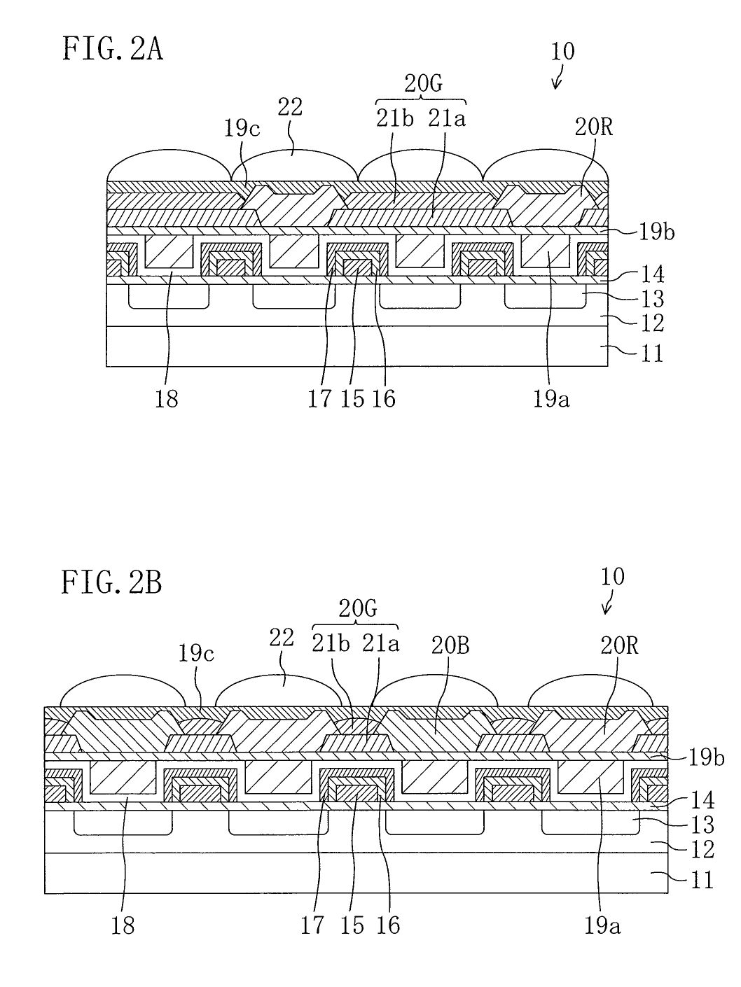

FIG. 2A shows a cross section taken along line IIa-IIa in FIG. 1, i.e., along a row of the color filter layer arrangement, and FIG. 2B shows a cross section taken along line IIb-IIb in FIG. 1, i.e., along a diagonal line of the color filter. What is shown in each of these figures accounts for four photoelectric transducers.

As shown in FIGS. 2A and 2B, a solid-state imaging device 10 of the present embodiment includes a semiconductor substrate 11 of a first conductivity type (e.g., N-type), and a semiconductor well (P well) layer 12 of a second conductivity type (e.g., P-type) opposite to the conductivity type of the semiconductor substrate 11, with a plurality of photoelectric transducers 13 formed in an upper portion of the P well layer 12. The photoelectric transducers 13 are formed by semiconductor regions of the first conductivity type, and are arranged in a matrix pattern as viewed from above.

A gate insulating film 14 is formed on the P well layer 12 and the photoelectric transducers 13. Transfer electrodes 15 of polycrystalline silicon are formed on the gate insulating film 14 between the photoelectric transducers 13 as viewed from above. An interlayer insulating film 16 for an insulative coating is formed on the upper surface and the side surface of the transfer electrode 15, and a light blocking film 17 of tungsten (W), or the like, is formed on the upper surface and the side surface of the interlayer insulating film 16 and on the upper surface of the semiconductor substrate 11 excluding the openings of the photoelectric transducers 13. A passivation film 18 of a silicon oxynitride film (SiON), or the like, is formed on the upper surface of the gate insulating film 14 and the light blocking film 17. Since the passivation film 18 is formed so as to cover the transfer electrodes 15, the interlayer insulating film 16 and the light blocking film 17 formed on the gate insulating film 14, the passivation film 18 is formed with depressed portions in portions where the passivation film 18 is in contact with the gate insulating film 14, i.e., in portions above the openings of the photoelectric transducers 13. A first transparent flattening layer 19a of a photosensitive transparent film whose main component is a phenol resin, or the like, is formed in the depressed portions, with the upper surface of the first transparent flattening layer 19a being flush with the upper surface of the passivation film 18.

A second transparent flattening layer 19b of an acrylic thermosetting transparent resin is formed on the flush surface formed by the passivation film 18 and the first transparent flattening layer 19a, and a color filter 20 including green filter layers 20G, red filter layers 20R and blue filter layers 20B is formed on the second transparent flattening layer 19b. Each color filter layer corresponds to one of the underlying photoelectric transducers 13.

Each green filter layer 20G includes a first green filter layer 21a being on the bottom layer of the color filter 20, and a second green filter layer 21b formed on the first green filter layer 21a and being the top layer of the color filter 20. The first green filter layer 21a and the second green filter layer 21b have thicknesses such that the first green filter layer 21a and the second green filter layer 21b together realize desirable spectral characteristics. Each green filter layer 20G is formed to be wider than the opening of the photoelectric transducer 13 so that the green filter layers 20G together from a checker pattern corresponding to the photoelectric transducers 13 as shown in FIG. 1. The first green filter layer 21a has a thickness less than or equal to that of the second green filter layer 21b and has an area greater than that of the second green filter layer 21b. The first green filter layers 21a and the second green filter layers 21b are provided so that edge portions of the red filter layers 20R and the blue filter layers 20B are interposed therebetween, thus forming a sandwich structure.

A third transparent flattening layer 19c of a thermosetting transparent resin whose main component is an acrylic resin is formed on the color filter 20, and an array of microlenses 22 is formed on the third transparent flattening layer 19c so that the microlenses 22 correspond to the pixels.

In the solid-state imaging device of the present embodiment, the color filter 20 is formed as follows. That is, the green filter layers 20G, which account for the largest portion of the sensing area among the red, green and blue color filter layers corresponding to the photoelectric transducers 13, are formed to be largest, wherein each green color filter layer 20G includes the first green filter layer 21a and the second green filter layer 21b, with the first green filter layer 21a being wider than, and having a thickness less than or equal to that of, the second green filter layer 21b. Therefore, in terms of the area with respect to the photoelectric transducer 13, the green filter layers 20G, which account for the largest portion of the sensing area, are larger than the red filter layers 20R or the blue filter layers 20B, thereby improving the adhesion with the second transparent flattening layer 19b. Moreover, with the green filter layer 20G being divided into two layers each having a smaller thickness, it is possible to increase process margins such as the focus margin, the exposure margin, and the alignment margin. Particularly, a green color resist has a low transmittance for ultraviolet radiation (e.g., the i line) used in the exposure step, and the photopolymerization is likely to be insufficient in deep portions, thus resulting in exfoliation. In the present embodiment, however, the two layers of a color resist are each exposed separately, whereby incident light is more likely to reach deep portions of the color resist. Thus, the photopolymerization will be sufficient, thus preventing exfoliation. Moreover, since over-exposure is not needed, the resolution in the edge portion will not be deteriorated, whereby it is possible to obtain a high-definition image with the solid-state imaging device.

The green filter layer 20G is formed by layering the second green filter layer 21b having a smaller area than the first green filter layer 21a on the first green filter layer 21a, with the edge portion of the red filter layer 20R and that of the blue filter layer 20B being interposed therebetween, thus forming a sandwich structure. Therefore, the edge portion of the red filter layer 20R and that of the blue filter layer 20B are formed on the first green filter layer 21a, whereby it is possible to prevent halation from the light blocking film 17, etc., and to improve the resolution in the edge portion. With the second green filter layer 21b being layered on the first green filter layer 21a, the adhesion therebetween is desirable, and the adhesion in the edge portion is also improved in a sandwich structure where the edge portion of the red filter layer 20R and that of the blue filter layer 20B are interposed therebetween, thus ensuring a sufficient margin for exfoliation.

Thus, the gap between adjacent the color filter layers along the edge portion of each pixel, particularly at the corner portions thereof, is substantially eliminated, whereby it is possible to maintain, at a certain level, the amount of scattered light of the incident light on the light blocking film 17, thus eliminating the sensitivity non-uniformity between pixels.

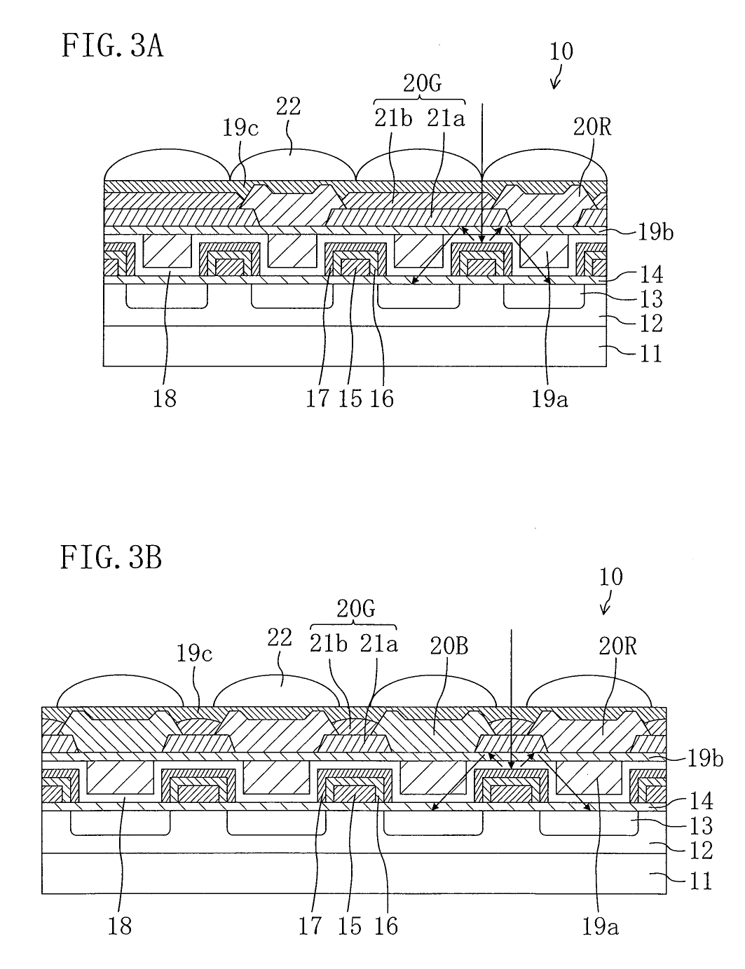

FIGS. 3A and 3B are cross-sectional views showing the solid-state imaging device of the present embodiment where light is incident on a pixel boundary portion, wherein FIG. 3A is a cross-sectional view taken along line IIa-IIa in FIG. 1, and FIG. 3B is a cross-sectional view taken along line IIb-IIb in FIG. 1.

Consider a case where a blue or red light beam substantially vertical to the semiconductor substrate 11 is incident on a pixel boundary portion, as shown in FIGS. 3A and 3B.

Since the green filter layer 20G is larger than the red filter layer 20R and the blue filter layer 20B, the green filter layer 20G is present in the region where a blue light beam incident on a pixel boundary portion passes through. Since the first green filter layer 21a and the second green filter layer 21b absorb most of the blue spectrum, there is only a small amount of blue light to be scattered at the surface of the light blocking film 17, etc. Therefore, there is substantially no increase in the amount of light to be received by the photoelectric transducer 13G corresponding to the green filter layer 20G surrounded by the blue filter layers 20B or the amount of light to be received by the photoelectric transducer 13G corresponding to the green filter layer 20G surrounded by the red filter layers 20R. Similarly, where red light is incident on a pixel boundary portion, since the green filter layer 20G absorbs most of the red spectrum, there is only a small amount of red light to be scattered at the surface of the light blocking film 17, etc. Therefore, there is substantially no increase in the amount of light to be received by the photoelectric transducer 13G corresponding to the green filter layer 20G surrounded by the blue filter layers 20B or the amount of light to be received by the photoelectric transducer 13G corresponding to the green filter layer 20G surrounded by the red filter layers 20R.

Therefore, no matter whether blue light or red light is incident, the amount of light to be received by the photoelectric transducer 13G corresponding to the green filter layer 20G surrounded by the blue filter layers 20B is not substantially different from the amount of light to be received by the photoelectric transducer 13G corresponding to the green filter layer 20G surrounded by the red filter layers 20R. Therefore, there is no line noise due to blue light and no line noise due to red light.

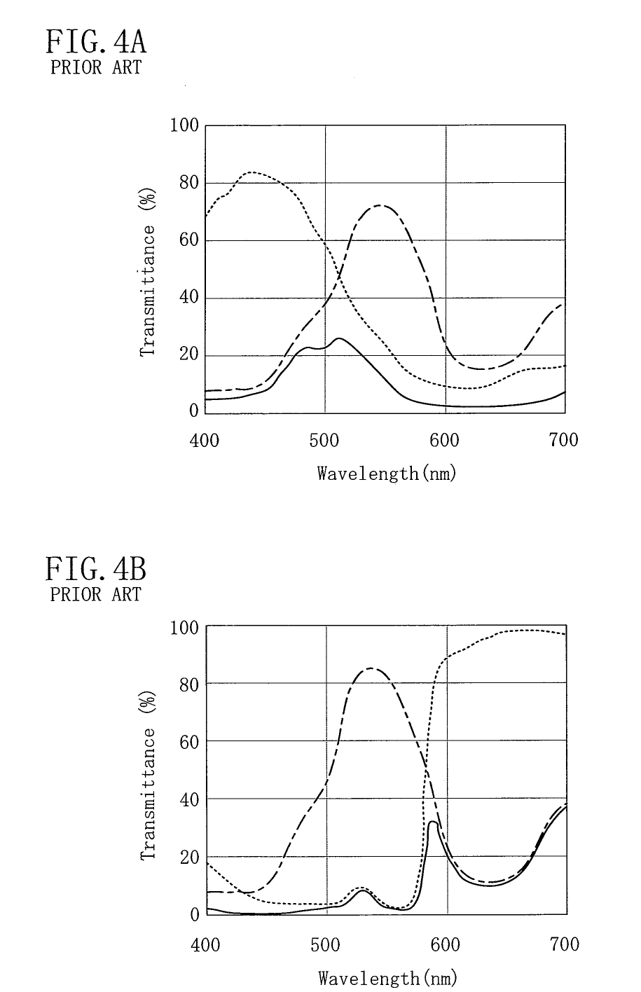

FIG. 4A shows spectral characteristics, showing the absorption of blue light by green filter layers, and FIG. 4B shows spectral characteristics, showing the absorption of red light by green filter layers. In FIGS. 4A and 4B, a dotted line represents the spectral characteristics of blue light or red light, a one-dot-chain line represents the spectral characteristics of the green filter layer, and a solid line represents the spectral characteristics of the absorption of blue light or red light by the green filter layer.

It can be seen from FIGS. 4A and 4B that blue light and red light are mostly absorbed by the green filter layer. It can also be seen that blue light or red light is transmitted intact through the filter if it does not pass through the green filter layer. Therefore, if the green filter layer 20G is larger than the red filter layer 20R and the blue filter layer 20B so that light entering between adjacent pixels passes through a portion of the green filter layer 20G, it is possible to substantially eliminate the influence of light entering between adjacent pixels and to prevent line noise.

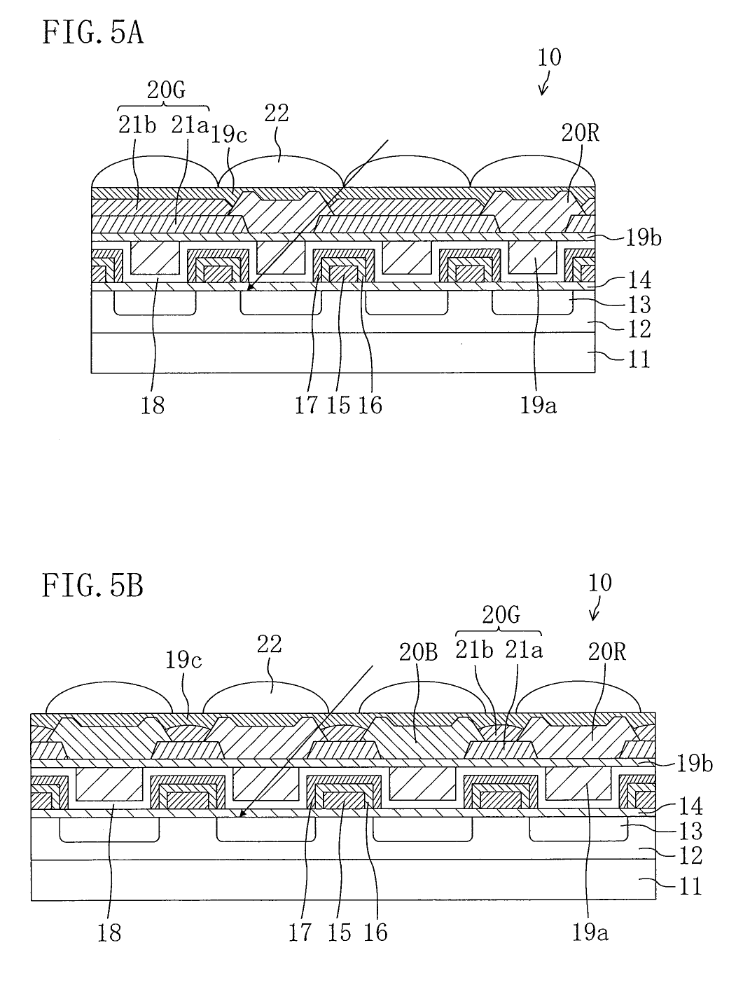

FIGS. 5A and 5B are cross-sectional views showing the solid-state imaging device of the present embodiment, where a light beam oblique with respect to the semiconductor substrate is incident on a pixel boundary portion, wherein FIG. 5A is a cross-sectional view taken along line IIa-IIa in FIG. 1, and FIG. 5B is a cross-sectional view taken along line IIb-IIb in FIG. 1.

As shown in FIGS. 5A and 5B, even if a light beam at an inclined angle with respect to the semiconductor substrate is incident on a pixel boundary portion of the solid-state imaging device of the present embodiment, the incident light beam passes only through the green filter layer 20G or passes through either the red filter layer 20R or the blue filter layer 20B, and it does not pass through both the green filter layer 20G and the red filter layer 20R or the blue filter layer 20B. Specifically, for each pixel, the green filter layer 20G is formed to be larger than the red filter layer 20R or the blue filter layer 20B, and the green filter layer 20G includes two layers including the first green filter layer 21a being the lower layer and the second green filter layer 21b being the upper layer, with the first green filter layer 21a being wider than, and having a thickness less than or equal to that of, the second green filter layer 21b, whereby even if an oblique light beam is incident on a pixel boundary portion, it is unlikely to be influenced by adjacent color filter layers. Therefore, it is possible to prevent mixture of colors in the blue filter layer 20B or the red filter layer 20R surrounded by the green filter layers 20G, thereby obtaining a high-definition image. Moreover, the sensitivity of the blue filter layer 20B or the red filter layer 20R surrounded by the green filter layers 20G will not be increased by mixture of colors from the adjacent green filter layers 20G.

Thus, in the solid-state imaging device of the present embodiment, the thickness of the first green filter layer 21a is less than or equal to ½ the desirable thickness, whereby it is possible to reduce the height and angle of the rise, from the semiconductor substrate 11, of the edge portion of the red filter layer 20R and the blue filter layer 20B formed on the first green filter layer 21a. Moreover, since the edge portion of the red filter layer 20R and the blue filter layer 20B is formed on the first green filter layer 21a, it is possible to reduce halation from the light blocking film 17. Moreover, since the red filter layer 20R and the blue filter layer 20B are formed with thinner edge portions, it is possible to precisely form the edge portions of the color filter layers.

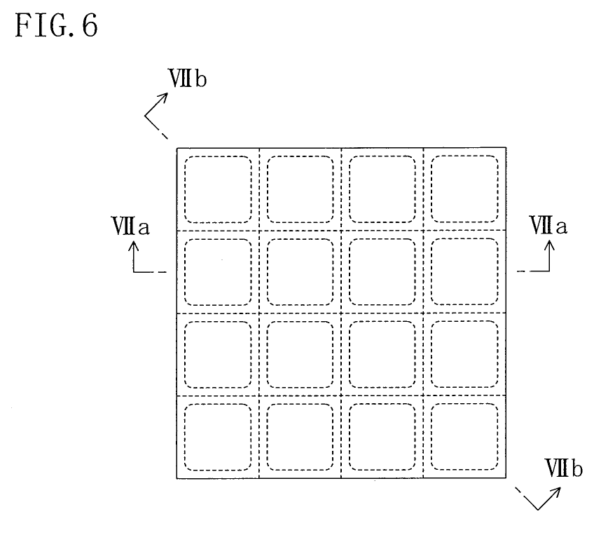

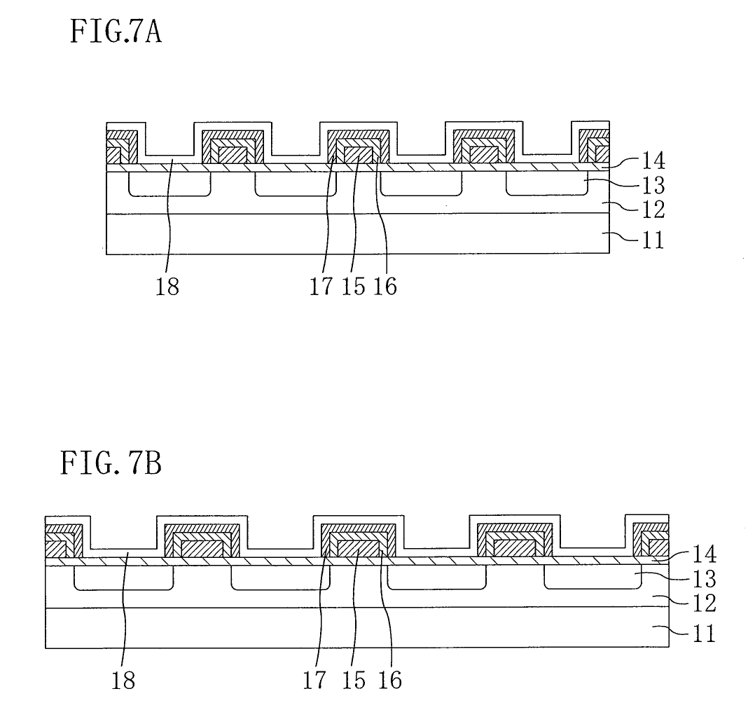

Next, a method for manufacturing the solid-state imaging device 10 of the present embodiment will be described with reference to FIGS. 6 to 13B. FIGS. 6, 8, 10 and 12 are plan views, and FIGS. 7A, 7B, 9A, 9B, 11A, 11B, 13A and 13B are cross-sectional views.

FIG. 6 is a plan view showing a manufacturing step where the passivation film 18 has been formed on the semiconductor substrate 11, as viewed from the side on which lenses are formed, FIG. 7A is a cross-sectional view taken along VIIa-VIIa in FIG. 6, and FIG. 7B is a cross-sectional view taken along line VIIb-VIIb in FIG. 6.

As shown in FIGS. 6, 7A and 7B, the solid-state imaging device 10 of the present embodiment includes the semiconductor substrate 11 of the first conductivity type, e.g., the N-type, and the P well layer 12 of the second conductivity type being the opposite conductivity to the first conductivity type formed on the semiconductor substrate 11, with a plurality of photoelectric transducers 13 being formed in an upper portion of the P well layer 12 from an N-type diffusion layer. As viewed from above, the photoelectric transducers 13 are arranged in a matrix pattern, and are formed by repeating the photolithography step, the ion implantation step and the thermal diffusion step.

Then, the gate insulating film 14 is formed on the P well layer 12 and the photoelectric transducers 13, and the transfer electrodes 15 of polycrystalline silicon are formed on the gate insulating film 14. The transfer electrodes 15 are each formed in a region between the photoelectric transducers 13 as viewed from above, and the surfaces thereof, i.e., the side surface and the upper surface thereof, are covered by the interlayer insulating film 16 for electrical insulation, with the light blocking film 17 of tungsten, or the like, being further formed so as to cover the interlayer insulating film 16.

Then, the passivation film 18 such as a boron-phosphorus silicon glass (BPSG film) or an SiON film is formed on the gate insulating film 14 and the light blocking film 17 by heat flow, for example. Although not shown in the figures, wiring of an aluminum alloy, or the like, is provided, and an SiON film, or the like, for example, is deposited in order to protect the wiring, and a bonding pad for electrode extraction is formed. At this point, there is a depressed portion in each region that is above the photoelectric transducer 13 and where the transfer electrode 15 is absent.

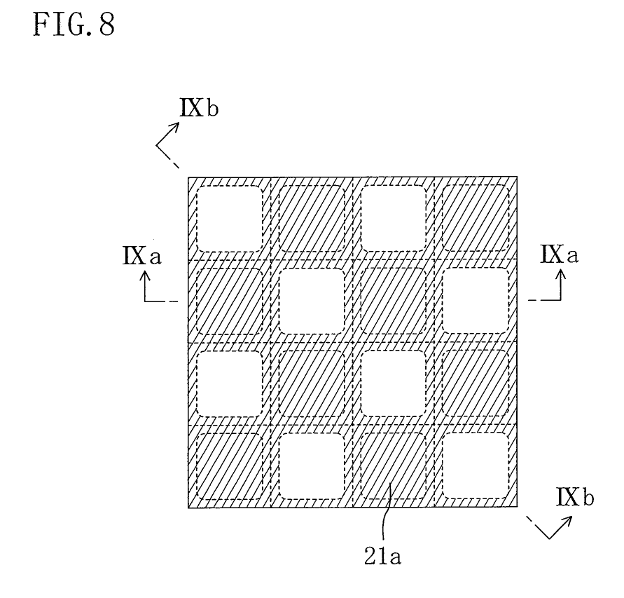

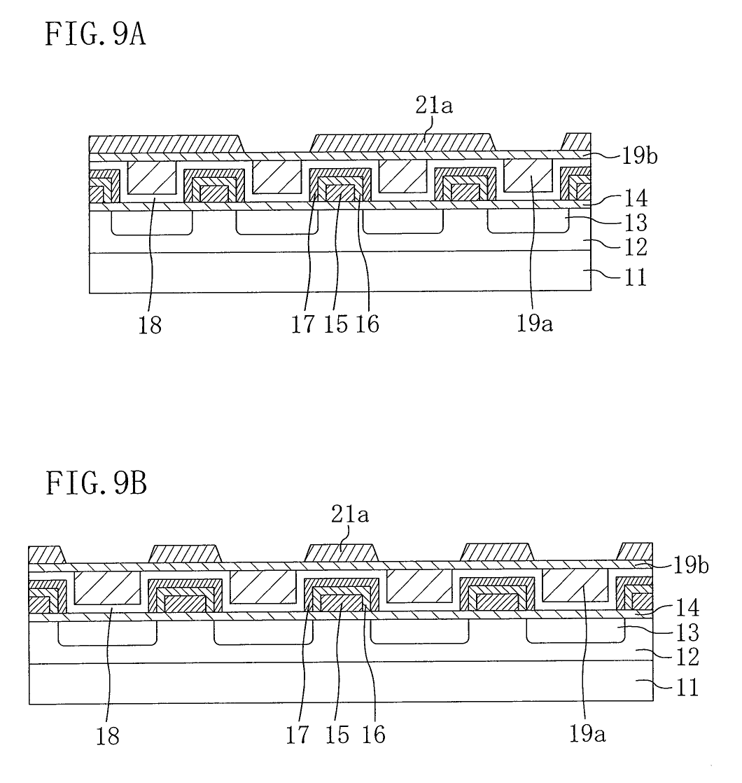

FIG. 8 is a plan view showing a manufacturing process at a point where the depressed portions in the passivation film 18 have been filled up with the first green filter layers 21a having been formed thereon, and FIGS. 9A and 9B are cross-sectional views taken along lines IXa-IXa and IXb-IXb, respectively, in FIG. 8.

As shown in FIGS. 8, 9A and 9B, the depressed portions between protruding portions formed by the provision of the transfer electrodes 15 and wiring on the N-type semiconductor substrate 11 are filled up with the first transparent flattening layer 19a as a pre-treatment for improving the precision of color filter layers to be formed in a subsequent step. The first transparent flattening layer 19a is formed by applying a photosensitive transparent resist whose main component is a phenol resin, for example, and performing an exposure and development process (including bleaching and baking) using a predetermined photomask. The transmittance is increased by ultraviolet irradiation. Instead of applying a photosensitive transparent resist and then exposing and developing the photosensitive transparent resist to fill up the depressed portions, the first transparent flattening layer 19a may be formed by, for example, applying a transparent resist in a plurality of iterations and then flattening the surface thereof by a known etch-back process, by applying a transparent film and then flattening the transparent film by a heat flow process, or by using a combination of these methods to further improve the flatness.

Then, the second transparent flattening layer 19b is formed on the passivation film 18 and the first transparent flattening layer 19a as a pre-treatment for improving the adhesion with the color filter and reducing the development residue. The second transparent flattening layer 19b is formed by, for example, applying an acrylic thermosetting transparent resin or a hexamethyldisilazane (HMDS) film on the passivation film 18 and the first transparent flattening layer 19a, and then performing a heat treatment to cure the applied film.

Then, the first green color filter layers 21a are formed in a checker pattern corresponding to the photoelectric transducers 13, as viewed from above, on the second transparent flattening layer 19b. The first green color filter layer 21a is formed by applying, on the second transparent flattening layer 19b, a photosensitive negative-type green color resist containing a dye or a pigment that is prepared so that light of the green wavelength range is selectively transmitted, and then performing an exposure step and a development step using a predetermined photomask. The first green filter layer 21a is formed using a photomask such that the first green filter layer 21a can be formed to be wider than the corresponding pixel so that there is no gap between color filter layers at the pixel boundary portion. The photosensitive negative-type green color resist is applied so that the thickness of the first green filter layer 21a is less than or equal to ½ the desirable thickness. The thickness is set taking into consideration various factors, such as, for example, suppressing the height and angle of the rise of the edge portion of the red filter layer 20R and the blue filter layer 20B to be formed later, reducing halation from the light blocking film 17, precisely defining the outline, and the possibility that the mask may be misaligned. Specifically, although a smaller thickness is preferred for suppressing the height and angle of the rise of the edge portion and the mask misalignment, a larger thickness is preferred for suppressing halation and precisely defining the outline. Taking into consideration a further reduction in the thickness, a green color resist for forming the first green filter layer 21a may be applied following the vapor deposition of an HMDS film, for example, instead of using the second transparent flattening layer 19b.

The width of the first green filter layer 21a will now be described.

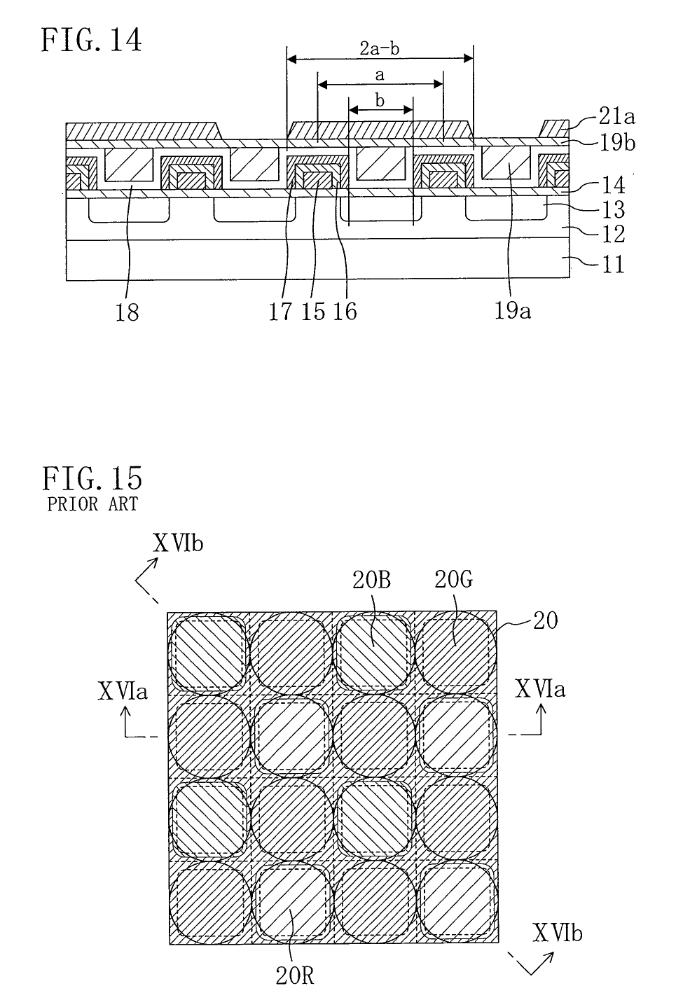

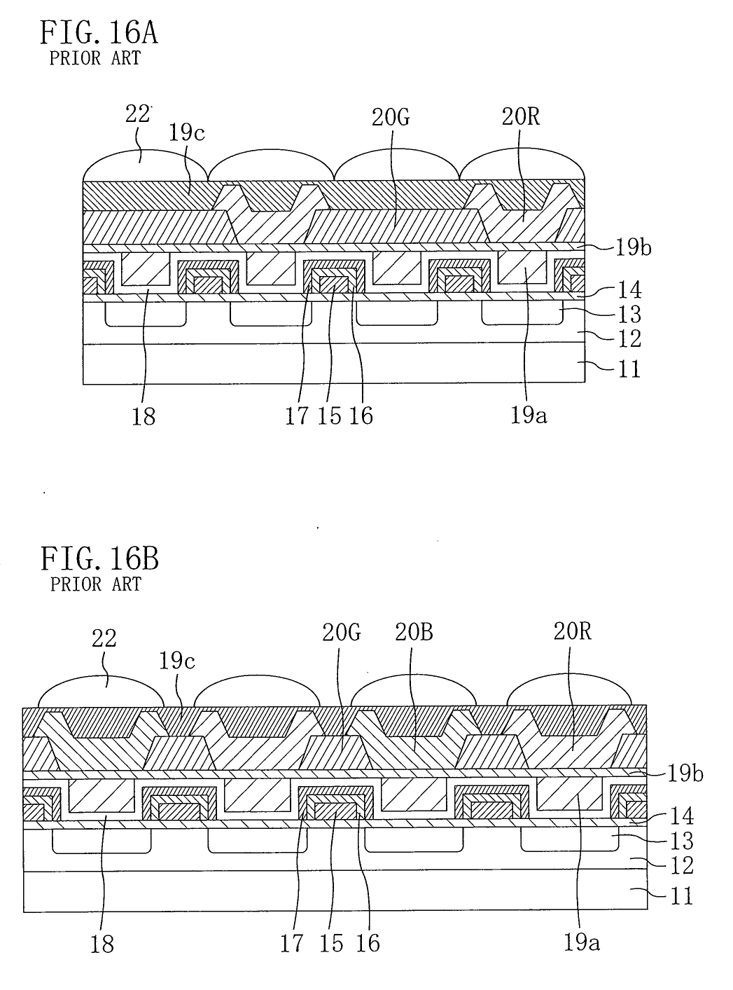

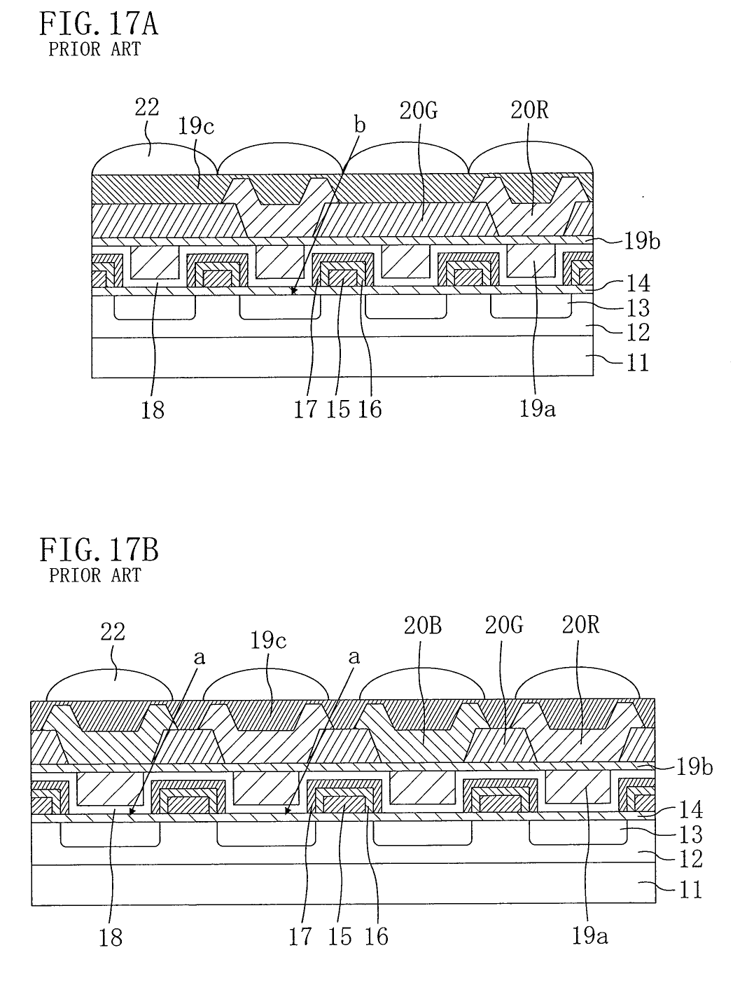

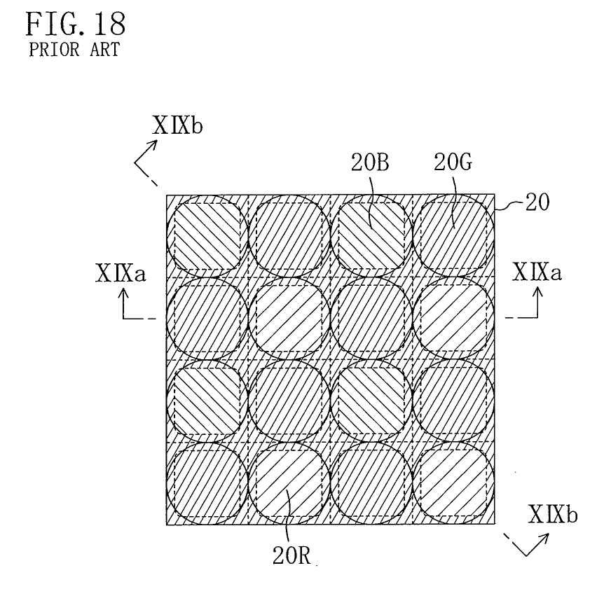

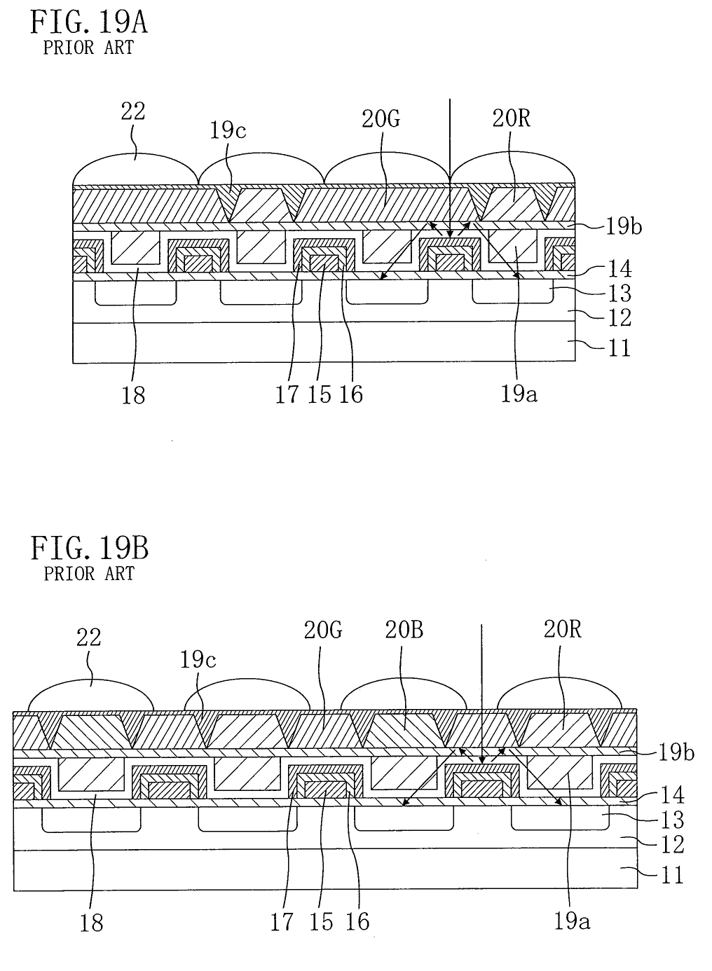

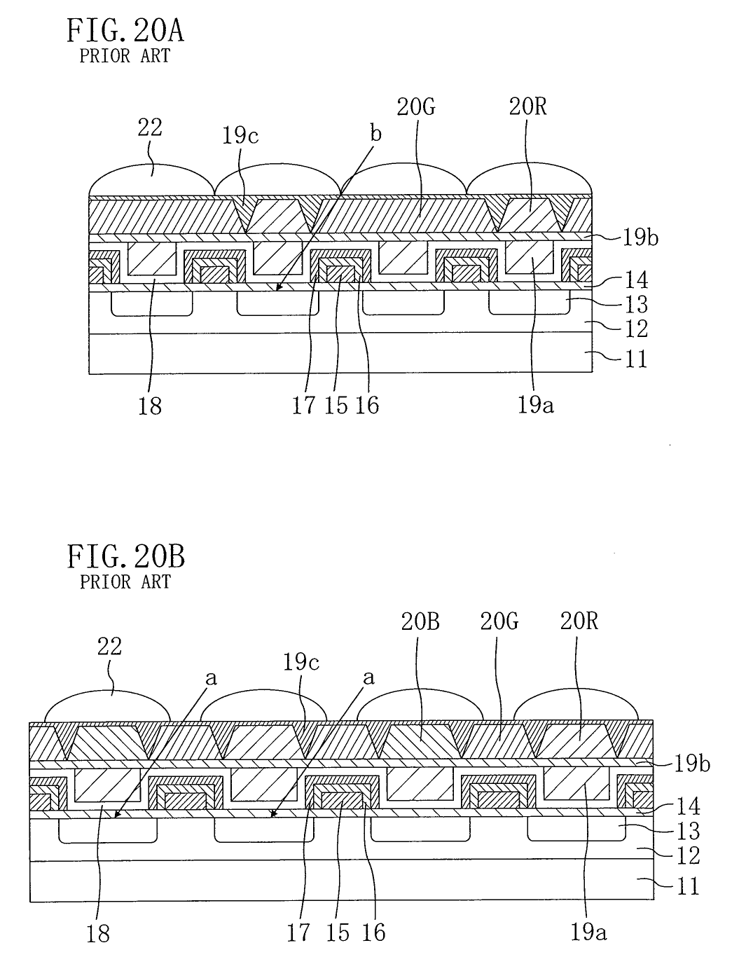

FIG. 14 is a cross-sectional view showing the width of the first green filter layer 21a.

Referring to FIG. 14, where “a” denotes the width of a unit pixel in the cross section taken in the column direction of unit pixels of the solid-state imaging device and “b” denotes the width of each opening in the passivation film 18 above a photoelectric transducer, the width of the first green filter layer 21a is set to be greater than “a” and less than or equal to “2a−b”. If the with of the first green filter layer 21a is set to be large, although the amount of overlap between color filter layers will be increased, the mask alignment margin will be small. If the width of the first green filter layer 21a is set to be small, a gap may be formed between color filter layers.

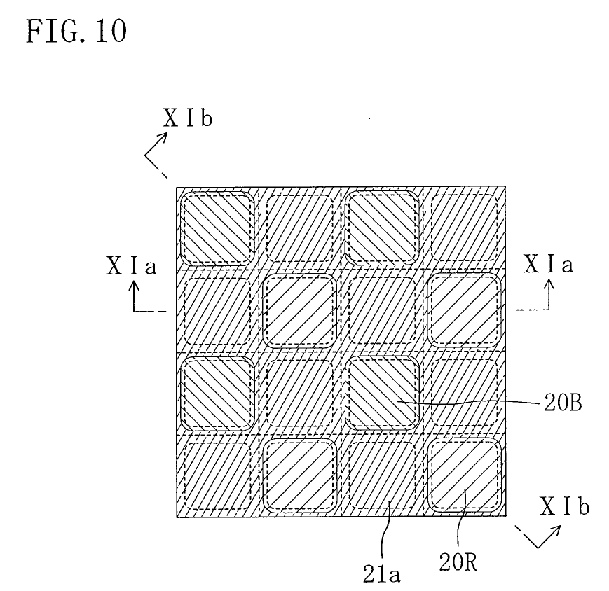

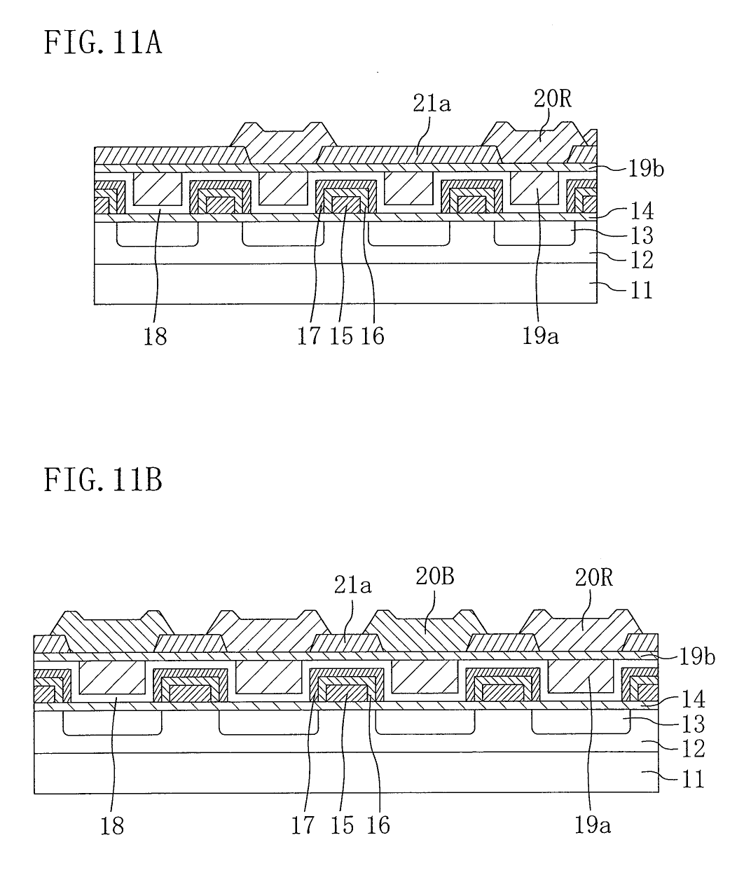

FIG. 10 is a plan view showing a manufacturing process at a point where the red filter layers 20R and the blue filter layers 20B have been formed, and FIGS. 11A and 11B are cross-sectional views taken along lines XIa-XIa and XIb-XIb, respectively, in FIG. 10.

As shown in FIGS. 10, 11A and 11B, after the formation of the first green filter layers 21a, the red filter layers 20R of the color filter 20 are formed. The red filter layers 20R are formed in every other rows and in every other columns so as to fill pixel positions where the first green filter layers 21a are absent. The red filter layers 20R are formed by applying a resist containing a dye or a pigment that is prepared so that light of the red wavelength range is selectively transmitted, and then performing an exposure step and a development step using a predetermined photomask, in a manner similar to that of the first green filter layers 21a. The red filter layer 20R is formed to be narrower than the first green filter layer 21a with the edge portion thereof being laid on the first green filter layer 21a.

Then, after the formation of the red filter layers 20R, the blue filter layers 20B are formed. The blue filter layers 20B are formed so as to fill pixel positions where the first green filter layers 21a and the red filter layers 20R are absent. The blue filter layers 20B are formed by applying a resist containing a dye or a pigment that is prepared so that light of the blue wavelength range is selectively transmitted, and then performing an exposure step and a development step using a predetermined photomask, in a manner similar to that of the red filter layers 20R. The blue filter layer 20B is formed to be narrower than the first green filter layer 21a with the edge portion thereof being laid on the first green filter layer 21a.

Although the blue filter layers 20B are formed after the formation of the red filter layers 20R in the illustrated example, the order of formation may be reversed as long as the red filter layers 20R and the blue filter layers 20B are formed after the formation of the first green filter layers 21a.

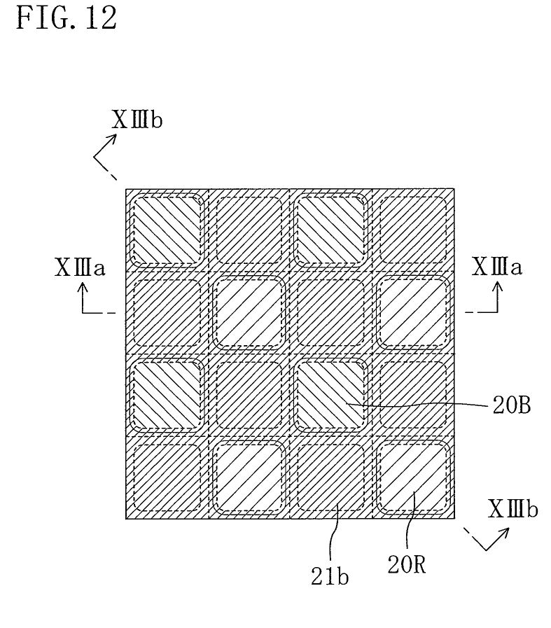

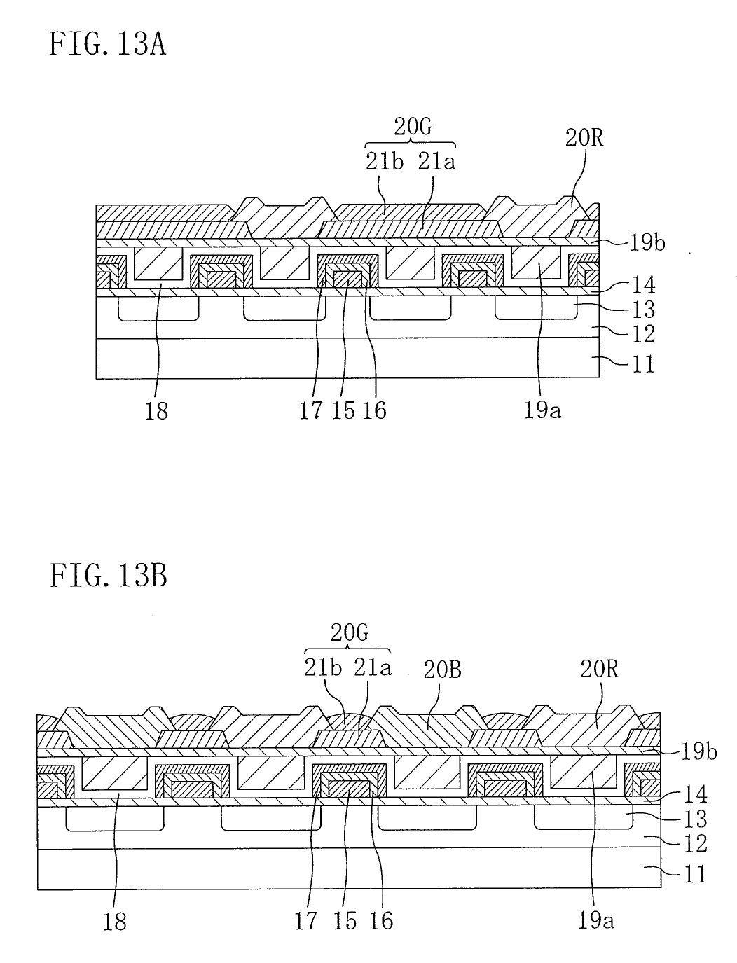

FIG. 12 is a plan view showing a manufacturing process at a point where the second green filter layers 21b have been formed on the first green filter layers 21a, and FIGS. 13A and 13B are cross-sectional views taken along lines XIIIa-XIIIa and XIIIb-XIIIb, respectively, in FIG. 12.

Referring to FIGS. 12, 13A and 13B, a photosensitive negative-type green color resist similar to a resist used for the first green filter layers 21a is applied over the first green filter layers 21a, the red filter layers 20R and the blue filter layers 20B. The photosensitive negative-type green color resist is applied to a thickness such that the combined green filter layer including the first and second green filter layers 21a and 21b will have a desirable thickness.

Then, an exposure process is performed using the same photomask as that used for the formation of the first green filter layers 21a. The exposure conditions are selected so that the width of the second green filter layer 21b is smaller than that of the first green filter layer 21a. Then, a development step is performed to form the second green filter layers 21b.

The second green filter layer 21b is formed as described above on the first green filter layer 21a with a smaller width than that of the first green filter layer 21a, with the edge portions of the red filter layers 20R and the blue filter layers 20B being interposed between the first green filter layers 21a and the second green filter layers 21b.

Then, although not shown in the figure, the third transparent flattening layer 19c is formed so that the microlenses 22 can be formed precisely. A thermosetting transparent resin whose main component is an acrylic resin, for example, is applied on the color filter 20, including the green filter layers 20G, the red filter layers 20R and the blue filter layers 20B, and the applied resin is cured by baking using a hot plate, or the like. The process is repeated a plurality of times to thereby form the third transparent flattening layer 19c, thus flattening the upper surface of the color filter 20. Then, in order to shorten the distance to the surface of the color filter 20 for the purpose of improving the sensitivity and also improving the dependency on the angle of incidence, the third transparent flattening layer 19c is etched to be as thin as possible by a known etch-back process.

Then, a photosensitive positive-type resist whose main component is a phenol resin is applied on the third transparent flattening layer 19c in positions above the photoelectric transducers 13, and an exposure and development process (including bleaching and baking) is performed, thereby forming the microlenses 22 each having a convex upper surface. The transmittance of the microlenses 22 is increased by ultraviolet irradiation. It is preferred that the post-baking of the microlenses 22 is performed at a temperature of 200° C. or less in order to prevent deterioration of the spectral characteristics of the color filter 20.

The solid-state imaging device 10 as shown in FIGS. 1, 2A and 2B is manufactured through steps as described above.

By the method for manufacturing a solid-state imaging device of the present embodiment, the green filter layer 20G is formed by two layers of the first green filter layer 21a and the second green filter layer 21b, with the edge portion of the red filter layer 20R and the blue filter layer 20B being interposed therebetween, thus forming a sandwich structure. Therefore, it is possible to prevent the formation of a gap between pixels, enabling the production of stable color filters. Thus, it is possible to prevent an oblique light beam incident on a pixel boundary portion from causing mixture of colors with adjacent color filter layers, and to eliminate the sensitivity non-uniformity. Moreover, it is possible to improve the optical characteristics such as line noise and color non-uniformity.

Moreover, with the green filter layer 20G being in a two-layer structure, it is possible to prevent the formation of a gap between pixels and to reduce the height and angle of the rise of the edge portion of the red filter layer 20R and the blue filter layer 20B formed on the first green filter layer 21a, whereby it is possible to shorten the distance from the lower surface of the microlens 22 to the photoelectric transducer 13. Therefore, it is possible to obtain a high-definition image with the solid-state imaging device.

Moreover, since the color filter layers can be formed with thin peripheral portions, it is possible to form the color filter 20 with a high precision. Therefore, it is possible to prevent color non-uniformity between pixels, and to improve line noise and color shading of the solid-state imaging device.

Moreover, the first green filter layers 21a and the second green filter layers 21b can be formed by using the same photomask. Thus, the characteristic structure of the solid-state imaging device of the present embodiment can be realized while suppressing an increase in the manufacturing cost.

The solid-state imaging device of the present embodiment and the method for manufacturing the same are not limited to the embodiment described above, but can be realized in various other embodiments without departing from the scope of the present invention.

For example, while the present embodiment is directed to a color filter of the primary color scheme for use in a solid-state imaging device where a higher priority is placed on the color tone, the present invention may be applied to a color filter of the complementary color scheme for use in a solid-state imaging device where a higher priority is placed on the resolution and the sensitivity. In the complementary color scheme, magenta, green, yellow and cyan light color filter layers are formed in a predetermined pattern according to a known color arrangement.

While color filter layers are formed in the present embodiment by using a resist containing a dye or a pigment prepared so that light of a predetermined wavelength is selectively transmitted, the resist containing a dye or a pigment may be a known dye-added color resist, a known pigment-dispersed color resist, or the like, or may be a combination of these resists.

Moreover, instead of using a photosensitive transparent resin and a known photolithography process, the first transparent flattening layer 19a may be formed by repeatedly applying a thermosetting transparent resin material and thermally curing the applied resin material, followed by an etch-back process of a known method.

While the second transparent flattening layer 19b is formed for the purpose of improving the adhesion of the color filter, it may be omitted as long as a sufficient adhesion strength is ensured.

The present embodiment of the invention is also applicable to a structure where an upward convex lens or a downward convex lens is formed on the photoelectric transducer 13 to further reinforce the light-collecting property.

The present embodiment of the invention is also applicable to a structure where a photomask which has been subjected to an exit pupil correction depending on the application is used for the formation of the color filter and the microlenses 22.

While the present embodiment is directed to a CCD-type solid-state imaging device, the present embodiment of the invention is also applicable to solid-state imaging devices of an amplification type such as a MOS type, or any other suitable type of solid-state imaging devices.

As described above, with the solid-state imaging device of the present invention and the method for manufacturing the same, it is possible to precisely form a color filter while preventing the exfoliation of color filter layers and the formation of a gap therebetween. Thus, the present invention is useful for a color solid-state imaging device including a color filter, a method for manufacturing the same, etc.

What is claimed is:

1. A solid-state imaging device, comprising:
photoelectric transducers arranged in a matrix pattern on a substrate; and
a plurality of color filter layers of different colors formed above the photoelectric transducers so as to correspond to the photoelectric transducers,
wherein one of the color filter layers of the color, which accounts for a largest area, is formed by two layers which are a bottom layer and a top layer of the color filter layers.

2. The solid-state imaging device of claim 1, wherein the bottom layer is wider than the top layer.

3. The solid-state imaging device of claim 2, wherein the top layer is wider than any of the other color filter layers.

4. The solid-state imaging device of claim 1, wherein:
the one of the color filter layers has a thickness such that a sum of a thickness of the bottom layer and that of the top layer yields desirable spectral characteristics; and
the thickness of the bottom layer is less than or equal to ½ the thickness of the one of the color filter layers.

5. The solid-state imaging device of claim 1, wherein:
the one of the color filter layers has a thickness such that a sum of a thickness of the bottom layer and that of the top layer yields desirable spectral characteristics; and
the thickness of the top layer is greater than or equal to ½ the thickness of the one of the color filter layers.

6. The solid-state imaging device of claim 1, wherein edge portions of the other color filter layers are interposed between the bottom layer and the top layer.

7. The solid-state imaging device of claim 1, wherein the one of the color filter layers is a green color filter layer.

8. The solid-state imaging device of claim 7, wherein the other color filter layers are red and blue color filter layers.

9. A method for manufacturing a solid-state imaging device, the solid-state imaging device including photoelectric transducers arranged in a matrix pattern on a substrate, and a plurality of color filter layers of different colors formed above the photoelectric transducers so as to correspond to the photoelectric transducers, the method comprising the steps of:
forming a first layer of one of the color filter layers, which accounts for a largest area, so that the first layer has a thickness less than or equal to ½ a thickness that yields desirable spectral characteristics;
forming other color filter layers so that edge portions of the other color filter layers are provided on the first layer; and
forming, on the first layer, a second layer of the one of the color filter layers having a width smaller than that of the first layer and a thickness greater than or equal to that of the first layer, so that the edge portions of the other color filter layers are interposed between the first layer and the second layer.

10. The method for manufacturing a solid-state imaging device of claim 9, wherein the first layer and the second layer are formed by using the same photomask.

11. The method for manufacturing a solid-state imaging device of claim 9, wherein the one of the color filter layers is a green color filter layer.

12. The method for manufacturing a solid-state imaging device of claim 11, wherein the other color filter layers are red and blue color filter layers.
